(19) United States
(12) Patent Application Publication
(10) Pub. No.: US 2009/0242996 A1
(43) Pub. Date: Oct. 1, 2009

(54) SOI TRANSISTOR WITH FLOATING BODY FOR INFORMATION STORAGE HAVING ASYMMETRIC DRAIN/SOURCE REGIONS

(76) Inventors: Ralf van Bentum, Moritzburg (DE); Nihar-Ranjan Mohapatra, Dresden (DE)

Correspondence Address: WILLIAMS, MORGAN & AMERSON, 10333 RICHMOND, SUITE 1100, HOUSTON, TX, 77042, US

(21) Appl. No.: 12/353,431

(22) Filed: Jan. 14, 2009

(30) Foreign Application Priority Data
Mar. 31, 2008 (DE) 10 2008 016 439.9

(51) Int. Cl. H01L 29/66; H01L 21/336

(52) U.S. Cl. 257/369; 438/302; 257/E21.409; 257/E29.166

(57) ABSTRACT

By laterally asymmetrically defining the well dopant concentration in a floating body storage transistor, an increased well dopant concentration may be provided at the drain side, while a moderately low concentration may remain in the rest of the floating body region. Consequently, compared to conventional symmetric designs, a reduction in the read/write voltages for switching on the parasitic bipolar transistor may be accomplished, while the increased punch-through immunity may allow further scaling of the gate length of the floating body storage transistor.

### BACKGROUND OF THE INVENTION

1. Field of the Invention

Generally, the present disclosure relates to the field of integrated circuits, and, more particularly, to field effect transistors in complex circuits which may include a memory area formed according to an SOI architecture, wherein information is stored by controlling charge in a floating body of an SOI transistor.

2. Description of the Related Art

Integrated circuits typically comprise a great number of circuit elements on a given chip area according to a specified circuit layout, wherein advanced devices may comprise millions of signal nodes that may be formed by using field effect transistors or MOS transistors. In the context of the present disclosure, the terms field effect transistors and MOS transistors are considered as synonyms. Thus, field effect transistors may represent a dominant component of modern semiconductor products, wherein advances in performance and low integration volume are mainly associated with a reduction of size of the basic transistor structures. Generally, a plurality of process technologies are currently practiced, wherein, for complex circuitry, such as microprocessors, storage chips, ASICs (application specific ICs) and the like, MOS technology is currently one of the most promising approaches due to the superior characteristics in view of operating speed and/or power consumption and/or cost efficiency. During the fabrication of complex integrated circuits using MOS technology, millions of field effect transistors, i.e., N-channel transistors and/or P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Hence, in combination with the capability of rapidly creating a conductive channel near the insulating layer upon application of the control voltage to the gate electrode, the conductivity of the channel region substantially determines the performance of the MOS transistors. Thus, the latter aspect renders the reduction of the channel length a dominant design criterion for accomplishing an increase in the operating speed of the integrated circuits.

Due to the decreased dimensions of circuit elements, not only the performance of the individual transistor elements may be increased, but also their packing density may be improved, thereby providing the potential for incorporating increased functionality into a given chip area. For this reason, highly complex circuits have been developed, which may include different types of circuits, such as analog circuits, digital circuits and the like, thereby providing entire systems on a single chip (SoC). Furthermore, in sophisticated microcontroller devices, an increasing amount of storage capacity may be provided on chip within the CPU core, thereby also significantly enhancing the overall performance of modem computer devices. For example, in typical microcontroller designs, different types of storage devices may be incorporated to provide an acceptable compromise between die area consumption and information storage density on the one side versus operating speed on the other side. For instance, fast or temporary buffer memories, so-called cache memories, may be provided in the vicinity of the CPU core, wherein respective cache memories may be designed to allow for reduced access times compared to external storage devices. Since a reduced access time for a cache memory may typically be associated with a reduced storage density thereof, the cache memories may be arranged according to a specified memory hierarchy, wherein a level 1 cache memory may represent the memory formed in accordance with the fastest available memory technology. For example, static RAM memories may be formed on the basis of registers, thereby enabling an access time determined by the switching speed of the corresponding transistors in the registers. Typically, a plurality of transistors may be required to implement a corresponding static RAM cell. In currently practiced approaches, up to six transistors may typically be used for a single RAM memory cell, thereby significantly reducing the information storage density compared, for instance, to dynamic RAM memories including a storage capacitor in combination with a pass transistor. However, usage of storage capacitors may require a regular refreshing of the charge stored in the capacitor while also writing to and reading from the dynamic RAM memory cell may require relatively long access times to appropriately charge and discharge the storage capacitor. Thus, although a high information storage density is provided, in particular, when vertical storage capacitor designs are considered, these memory devices may not be operated with high frequency and, therefore, dynamic RAM memories may typically be used for chip internal memories, for which an increased access time may be acceptable. For example, typical cache memories of level 3 may be implemented, in some cases, in the form of dynamic RAM memories to enhance information density within the CPU, while only moderately sacrificing overall performance.

Moreover, in view of further enhancing device performance, in particular with respect to individual transistor elements, the SOI (semiconductor or silicon on insulator) architecture has continuously been gaining in importance for manufacturing fast transistors due to their characteristics of a reduced parasitic capacitance of the PN junction, thereby allowing higher switching speeds compared to bulk transistors. In SOI transistors, the semiconductor region separating the drain and source regions and accommodating the channel regions, also referred to as body region, is dielectrically encapsulated. This configuration provides significant advantages, but also gives rise to a plurality of issues. Contrary to the body of bulk devices, which is electrically connected to the substrate, and thus applying a specified potential to the substrate, maintaining the body of the bulk transistor at a specified potential, the body of SOI transistors is not connected to a specified reference potential. Hence, the body's potential may usually float, due to accumulating charge carriers which may be generated by impact ionization and the like, thereby leading to a variation of the threshold voltage (Vt) of the transistor, depending on the “switching history” of the transistor, which may also be referred to as hysteresis. The threshold voltage represents the voltage at which a conductive channel forms in the body region between the drain region and the source region of the transistor.

The floating body effect is considered disadvantageous for the operation of regular transistor elements, in particular for static RAM memory cells, since the operation-dependent threshold voltage variation may result in significant instabilities of the memory cell which may not be tolerable in view of data integrity of the memory cell. Consequently, in conventional SOI devices including memory blocks, the drive current fluctuations associated with the threshold voltage variations are taken into consideration by appropriate design measures in order to provide a sufficiently high drive current range of the SOI transistors in the memory block. However, with respect to increasing information density for memory devices compared to static RAM memories and also compared to dynamic RAM memories, as previously explained, the floating body effect and the variation of the threshold voltage associated therewith may be taken advantage of by using the floating body of an SOI transistor as a charge storage region. In this manner, information may be stored in the transistor itself, thereby no longer requiring a charge storage capacitor as in dynamic RAM cells while also providing the potential for achieving approximately five times the density of current static RAM memories typically comprising six transistor elements.

Consequently, so-called floating body storage transistors have been developed in which charge may be intentionally accumulated in the body region so as to represent a logic high or low state, depending on the memory technique.

FIG. 1a schematically illustrates a cross-sectional view of a conventional floating body storage transistor 100 in the form of an N-channel transistor comprising a substrate 101 including a buried insulating 102, above which is formed a silicon layer 103. Thus, the substrate 101, the buried insulating layer 102, for instance provided in the form of silicon dioxide, and the silicon layer 103 define an SOI configuration. The transistor 100 further comprises a gate electrode structure 104 including a gate electrode 104B formed on a gate insulation layer 104A. Moreover, a sidewall spacer structure 106 is formed on the sidewalls of the gate electrode structure 104. Furthermore, the storage transistor 100 comprises drain and source regions 105, each of which may comprise a lightly doped region 105B adjacent to the gate electrode structure 104 and a highly doped region 105A that is offset from the gate electrode structure 104, for instance, by a distance substantially defined by the sidewall spacer structure 106. The lightly doped regions 105B form respective PN junctions 105C with a body region 107, which represents a floating body region since electrical connection to the periphery may be established via the respective PN junctions 105C only. Furthermore, the transistor 100 may comprise respective contact areas 108, for instance comprised of an appropriate metal silicide and the like. Additionally, the transistor 100 may be connected to voltage nodes, indicated as V_{BC}, V_{WC} and V_{SC}, which may represent a bit line, a word line and a select line, or respective voltages conveyed by these lines as may typically be provided in memory areas.

The transistor 100 may be formed on the basis of well-established process techniques for forming SOI transistors, including processes for forming and patterning the gate electrode structure 104, forming the lightly doped region 105B on the basis of ion implantation, followed by the formation of the spacer structure 106, which may be used as an efficient implantation mask during the formation of the highly doped regions 105A. Appropriate anneal cycles may be performed to activate the dopants and re-crystallize any damage in the silicon layer 103. Thereafter, the contact areas 108 may be formed and an appropriate contact structure and metallization system may be established to obtain the bit line, the word line and the select line or source line.

During operation of the storage transistor 100, a moderately high voltage may be applied to the select line to create respective electron/hole pairs by impact ionization or band gap bending mechanisms, wherein holes as majority charge carriers for the body region 107 may accumulate in the body region, while the electrons may drain off via the select line due to the applied high voltage. Operating the transistor 100 in this high voltage mode may be understood by referring to the lateral parasitic bipolar transistor 109, which may represent an NPN transistor defined by the drain and source regions 105 and the floating body region 107. Thus, by taking advantage of the parasitic transistor 109, charge may be created and accumulated in the body region 107, which may then significantly affect the threshold voltage of the transistor 100, which, although being considered as disadvantageous in standard SOI transistors, may be used for storing information in the transistor 100. Thus, the overall operational behavior of the storage transistor 100 may strongly depend on the characteristics of the parasitic transistor 109 and, thus, on the configuration of the body region 107 and the drain and source regions 105 including the lightly doped regions 105B. Consequently, the voltage provided at the select line may have to be adapted to the characteristics of the parasitic transistor 109 and, thus, to the overall configuration of the transistor 100.

FIG. 1b schematically illustrates a top view of a semiconductor device comprising an array 110 of storage transistors 100 with respective word lines, which may represent the gate electrode structures 104, a bit line 111 and a select line 112. Furthermore, as schematically illustrated, a control logic 120 may be connected to the array 110. Additionally, a voltage step-up converter 130 may be provided to create the required high voltages for operating the array 110. For example, the voltage step-up converter 130 may be provided in the form of a charge pump, wherein the area required for forming the circuit 130 on the substrate 101 of the device may typically increase as the degree of boosting the voltage increases. Consequently, the area consumed by the peripheral circuits, such as the circuit 130, may increase, if the voltage for operating the floating body RAM array 110 may increase. In addition, by applying a moderately high voltage to the transistor 100, respective leakage currents may also increase, thereby negatively impacting the retention time of the transistor 100.

Consequently, although transistors using the floating body as an efficient information storage component provide significant area saving compared to static RAM devices and dynamic RAM devices using a storage capacitor, moderately high voltages for programming and reading the floating body storage transistor may be required.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to semiconductor devices and techniques in which performance of floating body storage transistors may be enhanced by appropriately adapting the characteristics of a parasitic bipolar transistor and increasing the impact ionization probability locally at the drain side of the storage transistor. For this purpose, the basic doping of the well region may be accomplished in a laterally asymmetric manner with respect to drain and source areas, for instance, by appropriately providing implantation conditions so as to laterally asymmetrically pattern the well dopant concentration, so that the overall characteristics of the storage transistor and the parasitic bipolar transistor may be enhanced. That is, in the floating body region of the storage transistor, the basic well dopant concentration may be adapted so as to maintain the low concentration level for reducing the probability for charge carrier re-combination, which may be advantageous in maintaining a desired charge storage in the floating body. On the other hand, the probability of impact ionization may be locally increased at the drain side, thereby increasing the probability of creating charge carriers during the operation of the storage transistor, which may also result in a more efficient switching on of the parasitic bipolar transistor at reduced collector/emitter voltages compared to conventional designs. Consequently, reduced operating voltages for the storage transistor, possibly in combination with enhanced scalability thereof, may result in an overall performance enhancement of floating body storage transistors.

One illustrative floating body storage transistor disclosed herein comprises a gate electrode formed above a semiconductor region and separated therefrom by a gate insulation layer. The floating body storage transistor further comprises a drain region and a source region formed in the semiconductor region, wherein the drain and source regions are defined by a dopant species of a first conductivity type. Additionally, the transistor comprises a floating body region located in the semiconductor region adjacent to and in contact with the drain region and the source region so as to form a first PN junction with the drain region and a second PN junction with the source region. Furthermore, the floating body region is defined by a dopant species of a second conductivity type that is different from the first conductivity type, wherein a concentration of the dopant species of the second conductivity type is higher at the first PN junction compared to the concentration at the second PN junction, at least at a specified depth in the semiconductor region.

One illustrative semiconductor device disclosed herein comprises a plurality of floating body storage transistors configured to store information on the basis of charge storage in a floating body region, wherein each of the plurality of floating body storage transistors has a well region with an increased well dopant concentration at a PN junction at a drain side compared to a PN junction at a source side, at least at a specified depth of the well region.

One illustrative method disclosed herein relates to forming a storage transistor. The method comprises defining a well region in a semiconductor region in a laterally asymmetric manner with respect to a drain region and a source region to be formed in the well region. The method additionally comprises forming the drain region and the source region by introducing a dopant species of a first conductivity type to define a first PN junction connecting to the drain region and a second PN junction connecting to the source region.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a floating body storage transistor in a memory cell, according to conventional techniques;

FIG. 1b schematically illustrates an array of conventional floating body transistors with a voltage step-up converter, according to conventional approaches;

FIGS. 2a-2e schematically illustrate cross-sectional views of a storage transistor during various manufacturing stages, according to illustrative embodiments, in which asymmetric halo regions are formed on the basis of a tilted implantation process;

FIG. 2f schematically illustrates a cross-sectional view of a floating body storage transistor in an advanced manufacturing stage according to a P-channel transistor, according to still further illustrative embodiments;

FIG. 2g schematically illustrates a cross-sectional view of a plurality of floating body storage transistors in an advanced manufacturing stage, wherein a bulk configuration on the basis of isolated well regions may be used, in accordance with illustrative embodiments;

FIGS. 2h-2i schematically illustrate cross-sectional views during various manufacturing stages in providing a laterally asymmetric well dopant concentration on the basis of an additional implantation mask for covering the source region, according to further illustrative embodiments;

FIGS. 2j-2k schematically illustrate cross-sectional views of a floating body storage transistor during the formation of an asymmetric well doping prior to forming a gate electrode structure, according to still other illustrative embodiments;

FIGS. 2l-2m schematically illustrate a cross-sectional view and a top view, respectively, of a semiconductor device including a memory array based on floating body storage transistors, according to illustrative embodiments; and

FIG. 2n-2o schematically illustrate block diagrams of semiconductor devices including an asymmetric floating body RAM area in combination with other functional blocks, according to still other illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to semiconductor devices and techniques for forming the same, wherein floating body storage transistors (FB transistors) may be provided with an asymmetric configuration with respect to the lateral dopant concentration for defining a well region of the transistor to enhance performance by increasing impact ionization and/or reducing carrier recombination in the floating body region and/or reducing the required voltage for switching on the parasitic bipolar transistor. To this end, the definition of the well region, prior to forming the gate electrode or after forming the gate electrode, may be appropriately designed to obtain an increased well dopant concentration at the vicinity of the drain area, while maintaining a desired low well dopant concentration in the floating body area and possibly in the source area. Consequently, a high degree of impact ionization may be achieved at the drain side of the storage transistor during operation due to the increased well dopant concentration in combination with the drain dopant concentration. Moreover, in this configuration, a desired steep dopant gradient may be accomplished in the PN junction at the drain side. Additionally, a moderately low dopant concentration in the floating body region may be maintained to reduce the probability of charge carrier recombination, thereby providing an increased retention time for charge carriers created during the impact ionization and accumulating in the floating body region, which may be used for storing information in the storage transistor, as previously explained. In addition, the increased well dopant concentration at the drain side may also reduce the punch through effect. Hence, for given operating voltages, additionally or alternatively to a reduced overall well dopant concentration, a shorter gate length may also be used, thereby enabling further scalability of the storage transistor. On the other hand, a moderately low well dopant concentration at the emitter side or source side may result in high emitter efficiency of the parasitic bipolar transistor, thereby also contributing to enhanced scalability and reduced programming/reading voltages of the bipolar transistor, since it may turn on at a lower drain/source voltage.

In some illustrative aspects disclosed herein, the laterally asymmetric configuration of the well dopant concentration may be accomplished by performing a halo implantation process to asymmetrically introduce the dopant species for the well dopant concentration, which may be accomplished in some illustrative embodiments on the basis of incorporating at least one tilted implantation process during the formation of halo regions and/or by performing a well dopant implantation sequence including at least one masked implantation step. For example, after performing a symmetric basic well dopant implantation process, a further implantation process may be performed after forming the gate electrode structure, wherein the source side of the transistor may be masked, for instance by resist material, thereby obtaining a desired increased well dopant concentration at the drain side. In still other illustrative embodiments, the masked implantation process during defining the well dopant concentration may be performed prior to forming the gate electrode structure on the basis of an additional lithography step. Consequently, enhanced transistor devices may be formed on the basis of asymmetric floating body storage transistors due to a reduced size thereof, possibly in combination with a reduced size of any peripheral components, such as charge pumps and the like, which may also be reduced in size due to the enhanced performance of the parasitic bipolar transistor in respective floating body memory cells.

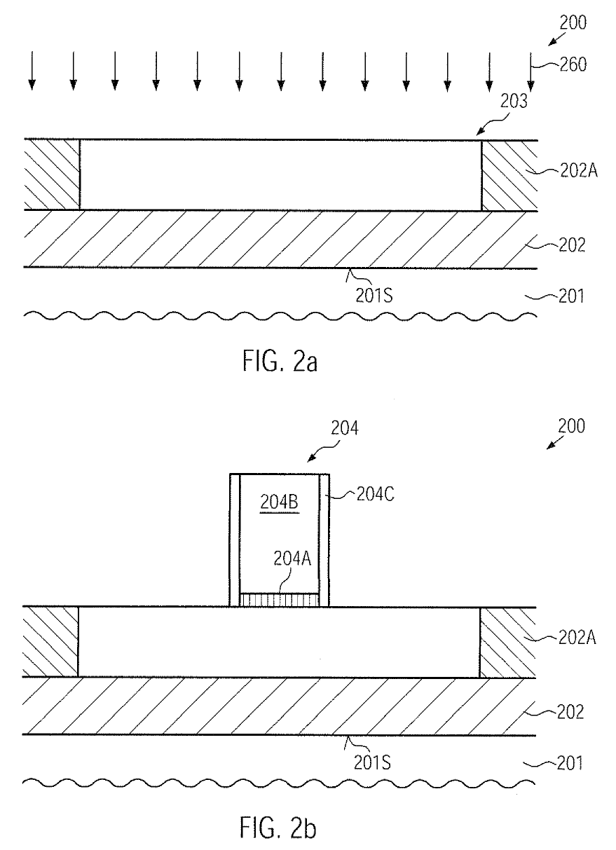

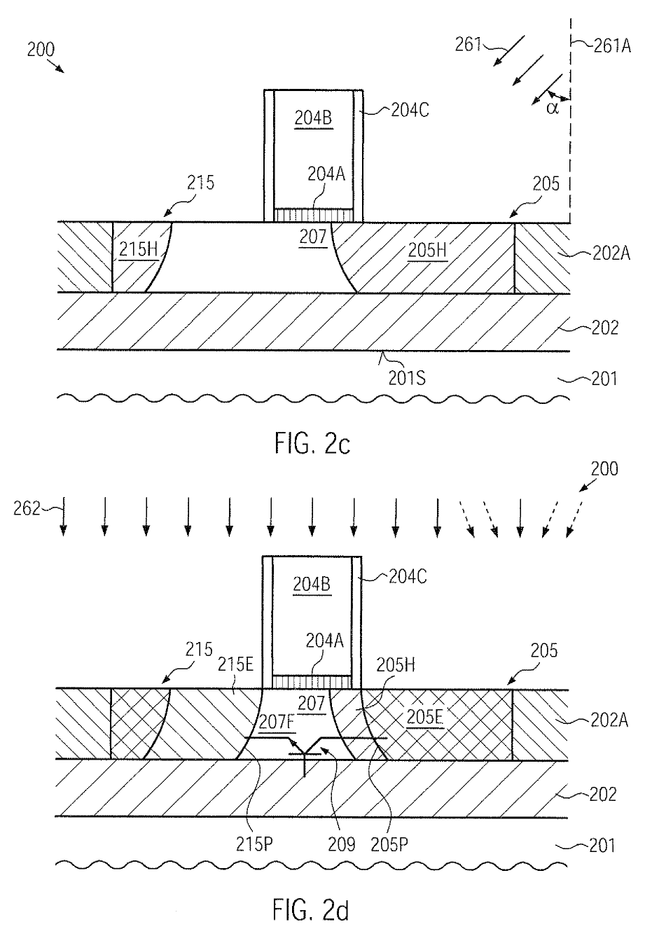

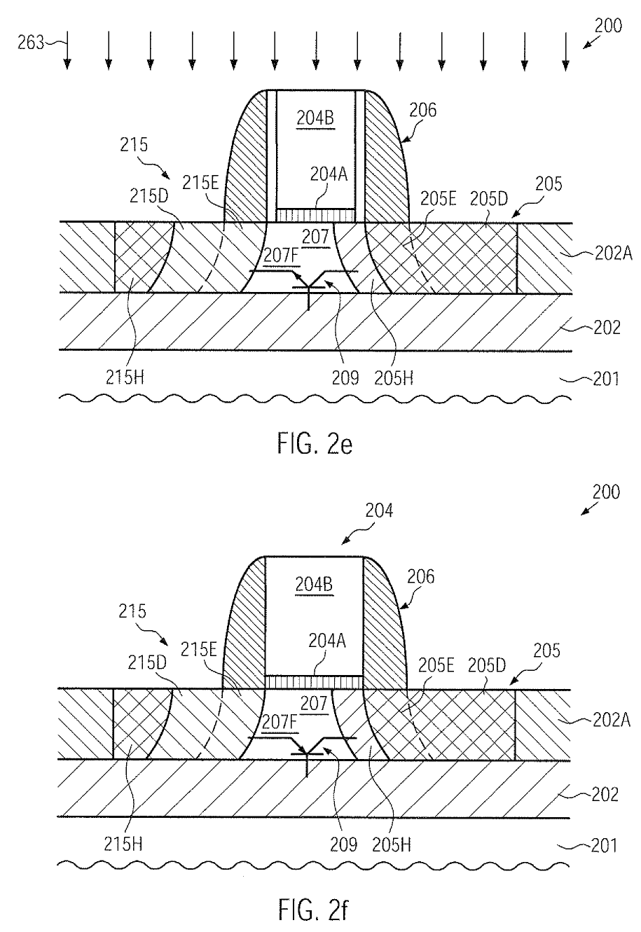

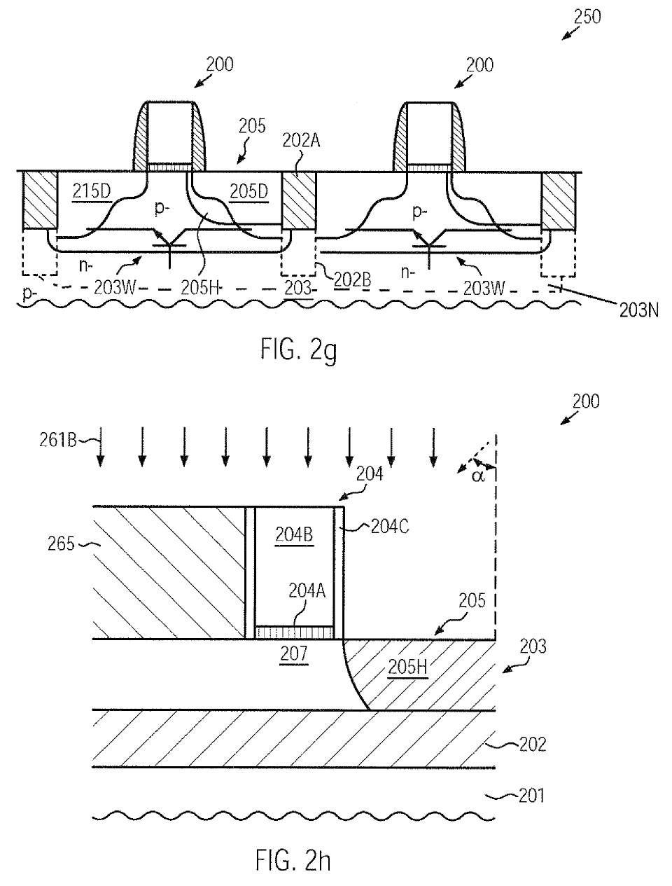

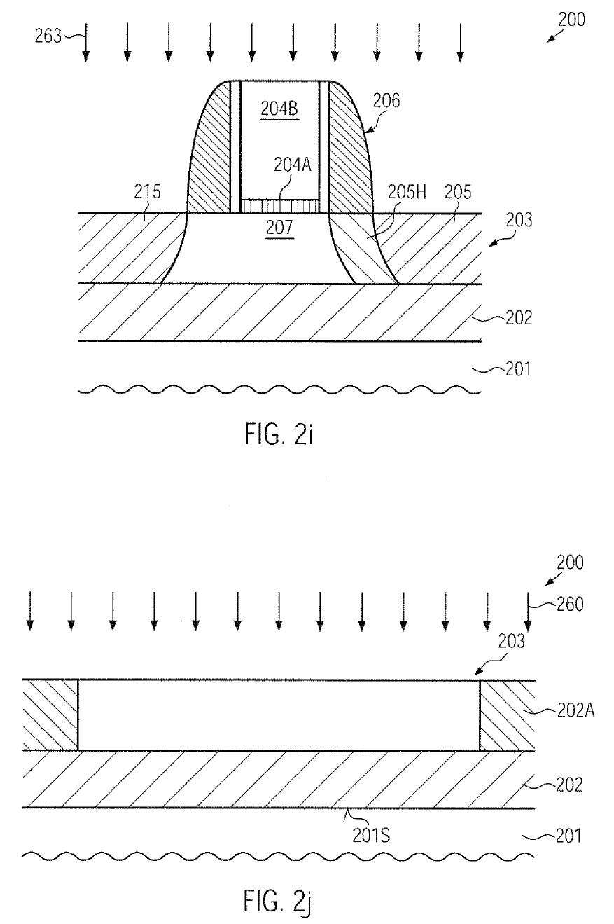

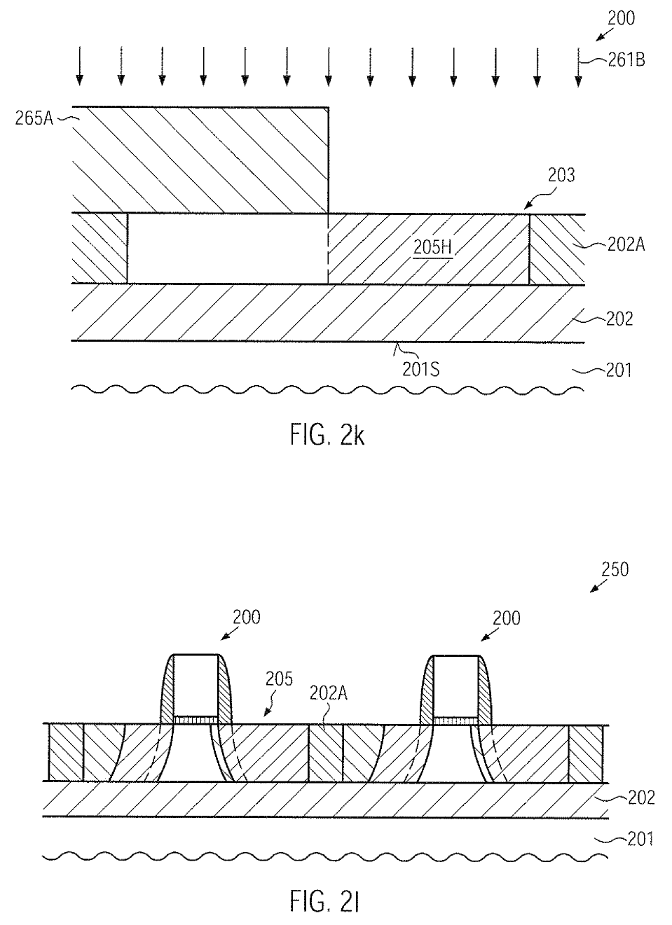

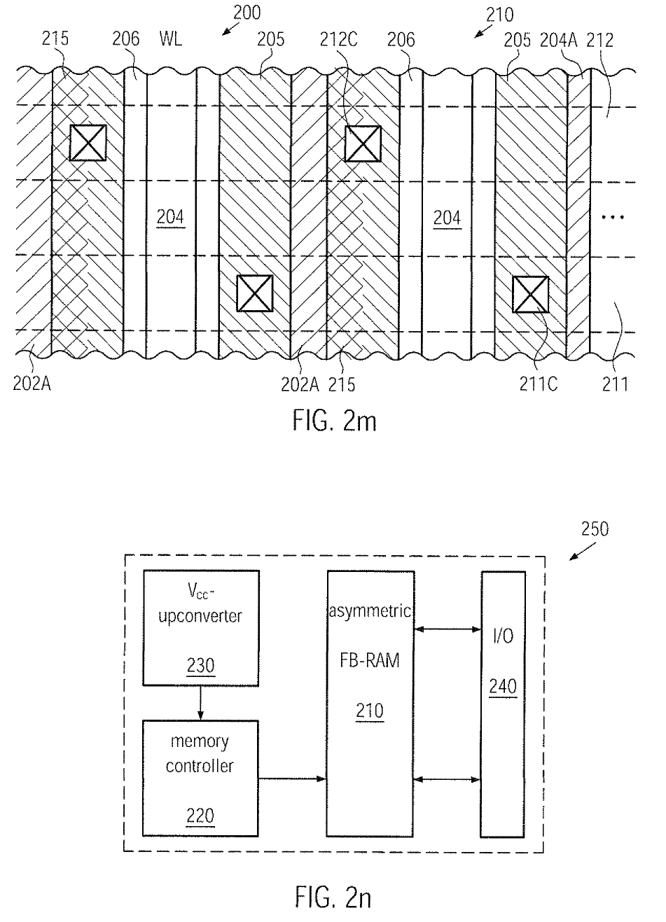

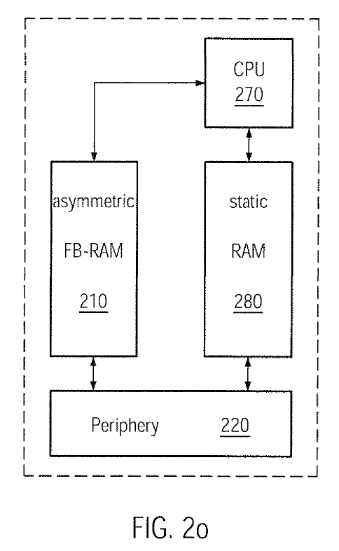

FIG. 2a schematically illustrates a semiconductor device 200 which may, in some illustrative embodiments, represent a floating body storage transistor. The transistor 200 may comprise a substrate 201, which may represent any appropriate carrier material for forming thereabove a semiconductor layer or region 203, in and above which further components of the transistor 200 may be formed. For instance, the substrate 201 may represent a semiconductor material, such as silicon, germanium and the like, while the semiconductor region 203 may represent an upper portion thereof, when a bulk configuration is considered, as will be described later on in more detail. In the embodiment shown, the transistor 200 may comprise a buried insulating layer 202, for instance in the form of any appropriate insulating material, such as silicon dioxide, silicon nitride and the like, which is located between the substrate 201 and the semiconductor region 203, thereby defining an SOI (semiconductor-on-insulator) configuration, at least at specified areas of the substrate 201. That is, the SOI configuration shown in FIG. 2a may be locally provided in the substrate 201 for the device 200, while, in other areas, a bulk configuration may be used, wherein respective semiconductor regions may be in contact with the substrate material 201. In the embodiment shown, an isolation structure 202A may be provided such that the semiconductor region 203 may be laterally isolated from other semiconductor regions, while the buried insulating layer 202 may provide vertical isolation of the semiconductor region 203 with respect to the substrate material 201.

In this context, it should be appreciated that any positional information, such as “vertical,” “lateral,” “above,” “below” and the like, may be understood as a position information relative to the substrate material 201, i.e., with respect to an interface 201S defined by the buried insulating layer 202 and the substrate 201. In other cases, when a bulk configuration may be considered, a respective reference plane may be defined by a surface of the substrate 201. Consequently, in this sense, the semiconductor region 203 may be formed above the substrate 201 and on the buried insulating layer 202. Similarly, a lateral direction is to be understood as a direction substantially parallel to the interface 201S, while a vertical direction is to be understood as a direction that is substantially perpendicular to the interface 201S.

The semiconductor region 203 may be comprised of any appropriate material, such as silicon, germanium, a mixture of silicon and germanium, or any other semiconductor compounds as may be appropriate for forming transistor elements therein and thereon. In the embodiment shown in FIG. 2a, the semiconductor region 203 may also be considered as a well region for the transistor 200, since, in the SOI configuration shown, the entire semiconductor region 203 may serve for forming the drain and source regions, a channel region and a floating body region of the transistor 200.

The transistor 200 in the manufacturing stage as shown in FIG. 2a may be formed on the basis of well-established process techniques including, for instance, the formation of an SOI configuration, partially or completely across the substrate 201, followed by forming the isolation structure 202A, which may, for instance, include lithography, etch, deposition and planarization techniques. Prior to forming the isolation structure 202A, or thereafter, the transistor 200 may be subjected to an implantation process 260 that is designed to introduce a dopant species of a certain conductivity type to define the basic dopant concentration in the semiconductor or well region 203. For instance, during the implantation process 260, a P-type dopant species may be incorporated when the transistor 200 is to represent an N-channel transistor. Similarly, an N-type dopant species may be incorporated when a P-type transistor is considered. As previously explained, the implantation parameters may be appropriately selected to achieve a desired low basic well doping in order to maintain the charge carrier recombination in a floating body region still to be defined in the well region 203 at a low level. That is, contrary to conventional approaches for forming a floating body storage transistor, the basic dopant concentration may be adjusted such that the desired low probability for charge-carrier recombination may be achieved without having to take into consideration the characteristics of a PN junction at a drain side of the transistor 200. It should be appreciated that appropriate process parameters, for instance with respect to implant energy, dose and the like, for a given dopant species may be obtained on the basis of well-established techniques, such as simulation, experiment and the like.

FIG. 2b schematically illustrates the transistor 200 in a further advanced manufacturing stage in which a gate electrode structure 204 may be formed on the semiconductor or well region 203. In this manufacturing stage, the gate electrode structure 204 may comprise a gate electrode material 204B or a placeholder material in the form of a conductive or non-conductive material, which may be replaced by a conductive material in a later stage, if desired. Furthermore, the gate electrode structure 204 may comprise a gate insulation layer 204A comprised of any appropriate material, wherein the layer 204A may also be partially or completely removed and replaced by a different dielectric material, depending on the overall process strategy. Additionally, the structure 204 may comprise offset spacers 204C, for instance made of any appropriate dielectric material, such as silicon dioxide and the like. The gate electrode structure 204 may be formed on the basis of well-established patterning processes including the deposition of appropriate material for the layers 204A and 204B followed by sophisticated patterning regimes, thereby defining a length of the gate electrode 204B, that is, in FIG. 2b, the horizontal extension of the gate electrode 204B, which may be approximately 100 nm and significantly less in sophisticated applications, while a gate length above 100 nm may also be selected.

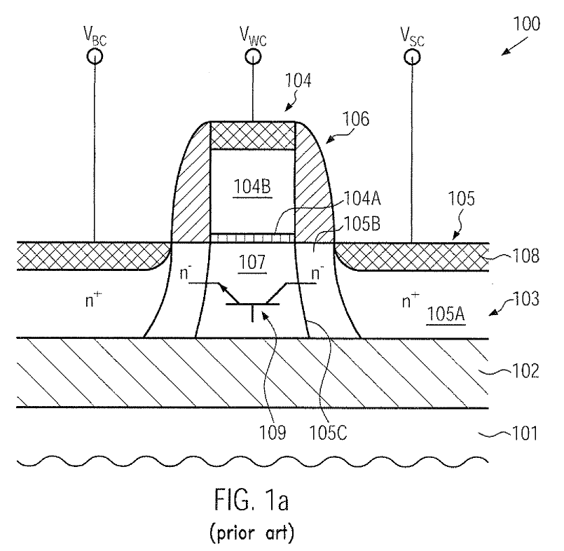

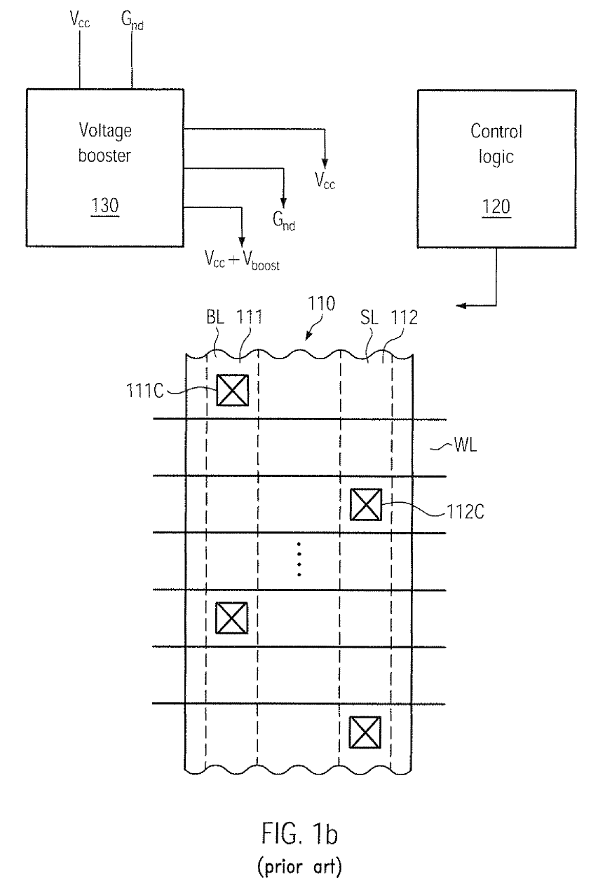

FIG. 2c schematically illustrates the transistor 200 in a further advanced manufacturing stage in which the basic well doping may be laterally asymmetrically modified in order to obtain enhanced performance of the transistor 200, as previously explained. Thus, in the embodiment shown, a further implantation process 261 may be performed, which may include at least one implantation step, in which the ion beam of the implantation process 261 may be directed to the surface of the well or semiconductor region 203 under a non-zero tilt angle alpha. In this respect, a direction substantially perpendicular to the reference plane 201S, as indicated by 261A, may be considered as an implantation direction that corresponds to a tilt angle of 0°. This may also be referred to as a straight or non-tilted implantation. Thus, during the process 261, a non-zero tilt angle alpha may be used to introduce the dopant species having the conductivity type as required for defining the well region such that an increased dopant concentration may be obtained at a drain side 205 so as to connect to a channel region 207, which may have received the respective basic well doping concentration during the process 260 (FIG. 1a), possibly in combination with additional implantation species for further defining a threshold voltage of the transistor 200 and the like. On the other hand, the gate electrode structure 204 may shield a portion of a source area 215, which therefore receives substantially no, or at least a significantly reduced, dopant concentration so as to define a respective offset between the gate electrode structure 204 and a region 215H of increased dopant concentration. Similarly, a region of increased dopant concentration 205H may be defined in the drain area 205, wherein this region may extend under the gate electrode structure 204 due to the tilt angle alpha used in the implantation process 261. The regions 205H, 215H may also be referred to as halo regions, the lateral position of which may be considered as laterally asymmetric with respect to the drain and source areas 205, 215 or with respect to the gate electrode structure 204.

During the implantation process 261, the respective implantation parameters, such as energy and dose, as well as the value of the tilt angle alpha, may be selected such that, in particular, the region 205H at the drain side 205 may be positioned with respect to the channel region 207 in accordance with device requirements, while also a concentration in the regions 205H, 215H may be adjusted such that a non-acceptable degree of counter-doping may be avoided during the further processing, i.e., the formation of extension regions, if extension regions are to be formed. For example, the implantation dose during the process 261 may be selected such that a concentration of the well dopant species in the regions 205H, 215H in combination with the previously performed basic doping may be obtained that is approximately one order of magnitude less than the dopant concentration of a dopant species for forming extension regions in the drain and source areas 205, 215. It should be appreciated, however, that any other appropriate dopant concentration may be selected for the regions 205H, 215H, as long as the degree of counter-doping is maintained below a predetermined threshold.

FIG. 2d schematically illustrates the transistor 200 in a further advanced manufacturing stage in which, according to one illustrative embodiment, a further implantation process 262 may be performed on the basis of a dopant species having an inverse conductivity type with respect to the regions 205H, 215H in order to define drain and source extension regions 205E, 215E. That is, during the implantation process 262, the process parameters, in particular the implantation dose, may be adjusted such that the finally obtained conductivity type may be determined by the dopant species introduced during the process 262 in portions of the drain and source areas 205, 215 which are exposed to the ion beam of the implantation process 262. Consequently, in the source area 215, the extension region 215E may have a varying degree of counter-doping due to a moderately low basic well doping adjacent to the gate electrode structure 204, which may increase towards the isolation structure 202A due to the previously formed halo region 215H. On the other hand, the extension region 205E may have a substantially higher degree of counter-doping due to the previously-formed halo region 205H, while additionally the remaining portion of the region 205H may define a desired steep dopant gradient at a first PN junction 205P. That is, the PN junction 205P may be defined by the dopant concentration introduced during the implantation process 262 including a certain degree of counter-doping created during the processes 260 and 261 and by the dopant concentration of the halo region 205H previously formed during the process 261, in combination with the previously performed basic well doping 260. Thus, if the extension regions 205E, 215E are to be provided, as shown in FIG. 2d, the corresponding implantation dose during the process 262 may be selected sufficiently high so as to obtain the desired dopant gradient at the PN junction 205P.

It should be appreciated that the implantation process 262 may also comprise one or more implantation steps performed on the basis of a non-zero tilt angle so as to appropriately design the shape of the extension regions 205E and/or 215E. For example, a tilt angle of appropriate magnitude may be selected to create an extension region 215E such that it may extend below the gate electrode structure 204 to enhance the characteristics of a parasitic transistor 209, which may be defined by the extension region 215 and a corresponding PN junction 215P (which may represent the emitter region of the transistor 209), a floating body region 207F (which may represent the base of the transistor 209 and which may comprise the remaining portion of the halo region 205H), and the drain extension region 205E (which may represent the collector region of the transistor 209). In other cases, the implantation process 262 may comprise additional tilted implantation steps, for instance also involving the drain side 205 so as to “push” the extension region 205E below the gate electrode structure 204, as desired in accordance with device requirements.

FIG. 2e schematically illustrates the transistor 200 in a further advanced manufacturing stage in which a spacer structure 206 may be formed on the sidewalls of the gate electrode structure 204 so as to act as an appropriate implantation mask during a further implantation process 263. During the process 263, a dopant species of the same conductivity type as previously incorporated during the process 262 may be introduced into exposed portions of the semiconductor region or well region 203, thereby forming highly doped drain and source regions 205D, 215D. Thus, the implantation parameters during the process 263 may be selected such that a desired penetration depth in combination with a desired high dopant concentration may be obtained. Consequently, in this manufacturing stage, the drain region or area 205 may be comprised of the heavily doped region 205D in combination with the extension region 205E, which are defined by a dopant species of a first conductivity type, which may be an N-type conductivity, when the transistor 200 represents an N-channel transistor and the parasitic bipolar transistor 209 thus represents an NPN transistor. On the other hand, the source area or region 215 may be comprised of the extension region 215E and the highly doped region 215D, wherein a degree of counter-doping may increase from the gate electrode structure 204 towards the isolation structure 202A due to the previously formed and laterally offset halo region 215H, as shown in FIG. 2c. Moreover, the halo region 205H having the increased concentration of a dopant species of a second conductivity type that is inverse to the first conductivity type may therefore define the PN junction 205P (FIG. 2d) so as to have a desired high dopant gradient, thereby increasing the probability of impact ionization at the drain side of the transistor 200, thereby resulting in increased charge-carrier creation, wherein the majority carriers with respect to the floating body region 207F may be accumulated therein, thereby enhancing the information storage capability of the transistor 200. That is, since halo region 205H may be provided in a highly asymmetric manner, a moderately high concentration may be used, as may be compatible with the formation of the extension regions 215E, 205E, as previously explained, while, on the other hand, a respective negative effect of an increased well doping concentration at the source side 215 may be substantially avoided. Consequently, the emitter efficiency of the parasitic transistor 209 may be maintained, while the enhanced impact ionization probability may provide increased charge-carrier storage capabilities while a moderately low basic well doping in the remaining portion of the floating body region 207F may provide a reduced charge-carrier recombination rate. Thus, upon operating the transistor 200, programming, i.e., creating charge carriers, and reading the information of the transistor 200 may be accomplished at reduced drain/source voltages, which may contribute to a reduced size of peripheral circuitry, as previously explained. Furthermore, the enhanced shielding effect of the asymmetrically positioned halo region 205H may enhance the punch-through behavior, thereby providing a reduced gate length for the gate electrode structure 204, which may thus translate into reduced transistor dimensions and thus increased information storage density.

After the implantation process 263, the further processing of the transistor 200 may be continued, for instance, by performing appropriate anneal processes to cure implantation-induced damage in the well or semiconductor region 203 and also activate the dopant species previously introduced during the implantation processes 260, 261, 262 and 263. It should be appreciated, however, that any intermediate anneal processes may have been performed, when deemed appropriate for the overall process strategy. Next, metal silicide regions may be formed, if required, for instance in the drain and source regions 205, 215 and also in the gate electrode structure 204. For this purpose, any well-established process strategies may be applied. Thereafter, an interlayer dielectric material, for instance in the form of silicon dioxide, silicon nitride and the like, possibly including highly-stressed material portions, may be formed to enclose and passivate the transistor 200, followed by the patterning of the inter-layer dielectric material to form a respective contact connecting to a contact area of the transistor 200, such as the drain and source regions 205, 215 and the gate electrode 204, thereby establishing a memory cell, which may be appropriately accessed on the basis of peripheral circuitry, as is explained above and as will also be explained later on in more detail.

FIG. 2f schematically illustrates the transistor 200 according to a further illustrative embodiment in which the transistor 200 may represent a P-channel transistor. That is, the basic doping of the semiconductor region 203, also referred to as well-doping, may be accomplished on the basis of an N-type dopant species so that the halo region 205H may also be comprised of N-type dopant species with appropriate concentration. Similarly, the highly doped regions 205D, 215D and the extension regions 205E, 215E, if provided, may be defined on the basis of a P-type dopant species. Also, the parasitic bipolar transistor 209 may now represent a PNP transistor, which may also switch into the conductive state at a reduced drain/source voltage compared to conventional storage transistors having a symmetric design with respect to the well doping, i.e., with respect to the lateral positioning of the halo regions 205H and 215H. Consequently, memory areas may also be efficiently formed on the basis of P-channel transistors, if required, or both types of transistors, i.e., N-channel transistors and P-channel transistors may be used for forming an appropriate memory array on the basis of floating body storage transistors.

FIG. 2g schematically illustrates a semiconductor device 250, which may comprise a plurality of floating body storage transistors 200 that may have a similar configuration as previously explained with reference to FIGS. 2a-2f, wherein, however, contrary to the embodiments previously shown, a bulk configuration may be used, at least partially. That is, the semiconductor device 250 may comprise the semiconductor region 203 in the form of a semiconductor material, such as a silicon layer, a germanium layer and the like, which may represent an upper portion of the substrate 201 and the like. Furthermore, the isolation structure 202A may be provided so as to laterally isolate the individual storage transistors 200, as previously explained. Moreover, appropriate well regions 203W may be provided in the semiconductor region 203 so as to be embedded therein, wherein the isolated well region 203W represents a portion of the semiconductor region 203, which may have received a basic well doping so as to define a PN junction with the remaining portion of the semiconductor region 203. Depending on the configuration of the semiconductor layer 203 and the conductivity type of the transistors 200, additional well regions, such as a well region 203N, may be provided to accommodate the well regions 203W. For example, when the transistors 200 represent N-channel transistors and the substrate 201 and the semiconductor layer 203 are pre-doped by a P-type dopant, the well region 203N may be an N-doped region, in which the P-doped well regions 203W are embedded.

Consequently, within the respective well regions 203W, a similar asymmetric configuration of the basic well doping may be provided, as previously explained, thereby also providing the advantages as previously explained. That is, the drain region 205D may be formed in the well region 203W on the basis of appropriate design parameters so as to define an abrupt PN junction with the asymmetrically positioned halo region 205H, while the remaining portion of the floating body region 207F may have a reduced basic well dopant concentration to increase performance of the parasitic transistor 209, as previously explained (FIG. 2f). Consequently, the concept of a laterally asymmetrically defined well dopant concentration may also be applied to a bulk configuration by appropriately isolating the respective well regions 203W of each transistor 200 and thus of each memory cell formed on the basis of the individual transistors 200. It should be appreciated that the dopant concentration of the well regions 203W, in combination with the concentration of the halo region 205H, are appropriately selected with respect to the desired specifications of the transistors 200, the operating voltage and the amount of charge to be stored. That is, the combined dopant concentration of the well region 203W and the halo region 205H may be designed with respect to the leakage currents such that too high a value of the leakage currents may be avoided in order to maintain the desired data retention time, i.e., avoiding undue recombination and excessive current flow into the body region.

The isolated well region 203W may be formed on the basis of appropriately designed implantation masks so as to provide a desired offset between neighboring well regions 203W and/or by forming the isolation structures 202A with a sufficient depth so as to extend beyond a depth of the well regions 203W, as indicated by the dashed lines 202B. It should be appreciated that the bulk configuration as shown in FIG. 2g may be combined with an SOI configuration on the same substrate, if considered appropriate in view of the overall device requirements.

With reference to FIGS. 2h-2k, further illustrative embodiments will now be described in which the transistor 200 may receive a laterally asymmetrically patterned well doping by performing an additional masked implantation step, wherein the embodiments described with reference to FIGS. 2h-2i may involve a respective masked implantation step after the formation of the gate electrode structure, while embodiments described with reference to FIGS. 2j-2k may include a masked implantation step prior to forming the gate electrode structure.

FIG. 2h schematically illustrates the transistor 200 in a manufacturing stage in which a basic desired well dopant concentration may have been incorporated into the semi-conductor region 203 and the gate electrode structure 204 if formed above the region 203. Furthermore, an implantation mask 265, for instance in the form of resist material, polymer material and the like or any other appropriate material, may be positioned above the region 203 to cover the source side 215, while exposing the drain side 205 to an implantation process 261B in order to incorporate additional well dopant species, thereby forming a “halo” region 205H. The implantation process 261B may, in one illustrative embodiment, be performed as a substantially straight or non-tilted implantation process, which may be an efficient approach, when the drain and source regions 205, 215 may be formed without providing respective extension regions, such as the regions 205E, 215E, as previously described. In other illustrative embodiments, the implantation process 261B may comprise a tilted implantation step using an appropriate angle, which may be selected to a moderately low value so that the desired “offset” to the gate electrode structure 204 at the source side 215 may be provided by the mask 265, irrespective of the magnitude of the tilt angle alpha. Thus, a high degree of flexibility with respect to selecting the process parameters for the implantation process 261B may be achieved, since a desired dopant concentration may be maintained in the source region 215 on the basis of the mask 265.

The device 200 shown in FIG. 2h may be formed on the basis of the following processes. After establishing the desired basic well dopant concentration in the semiconductor region 203, the gate electrode may be formed on the basis of well-established patterning regimes. Next, a material may be deposited, for instance in the form of a polymer material, a photoresist material, or any other dielectric material that may be removable with a high degree of selectivity after the implantation process 261B. For instance, resist material may be deposited in a highly non-conformal manner, for instance by spin-on techniques, and may be subsequently exposed to form an overlapping edge (not shown) with the gate electrode structure 204, while, in other cases, a planarization of the mask material may be accomplished, for instance by an appropriately designed chemical mechanical polishing (CMP) process, thereby improving overlay accuracy during the subsequent exposure process. Thus, the exposed portion or the non-exposed portion, depending on the type of material used, may be removed from above the drain area 205, wherein an overlay accuracy during the lithographic patterning may be substantially determined by the length of the gate electrode structure 204. In other cases, after providing an appropriate mask material and planarizing the same, a resist layer may be formed and may be patterned on the basis of the planarized surface topography so as to pattern the resist layer and the underlying mask material. After the implantation process 261B, the mask 265 may be removed, for instance by well-established selective etch techniques, to expose the source area 215.

FIG. 2i schematically illustrates the transistor 200 in a further advanced manufacturing stage in which the spacer structure 206 may be formed on the sidewalls of the gate electrode structure 204 in order to provide an implantation mask for the implantation process 263 for defining the dopant concentration in the drain and source regions 205, 215. In one illustrative embodiment, the spacer structure 206 may be formed prior to incorporating a dopant species for the drain and source regions 205, 215 so that a corresponding offset between the “halo region” 205H and drain region 205 may be adjusted on the basis of the spacer structure 206. Thus, when the process 261B may have been performed as a substantially non-tilted implantation process, a desired positioning of the PN junction 205P in the drain side may be accomplished on the basis of the spacer structure 206. For example, the spacer structure 206, in combination with appropriately designed anneal processes, may define the final shape of the drain and source regions 205, 215, while also ensuring that a respective abrupt PN junction may be obtained in the drain region 205 so as to enhance impact ionization, as previously explained. It should be appreciated, however, that a further spacer element may be formed, if a lateral profile of the drain and source regions 205, 215 with enhanced complexity may be required.

FIG. 2j schematically illustrates the transistor 200 in a manufacturing stage prior to forming the gate electrode structure 204. That is, the device 200 of FIG. 2j may substantially correspond to the device shown in FIG. 2a, wherein the implantation process 260 may be performed to define a basic well doping in the semiconductor region 203.

FIG. 2k schematically illustrates the device 200 with an implantation mask 265A so as to cover the source area 215 and a portion of an area corresponding to the gate electrode structure 204. The mask 265A may be formed on the basis of a lithography process, which may be performed on the basis of a substantially planar surface topography, thereby enhancing overall alignment accuracy and efficiency of the lithographical patterning process. For example, the mask 265A may be comprised of a resist material or any other appropriate material that may be patterned on the basis of a lithography process. Thereafter, the implantation process 261B may be performed to introduce a further dopant species to increase basic well doping at the drain side of the transistor 200. Next, the gate electrode structure 204 may be formed on the basis of manufacturing techniques, as previously described, wherein a corresponding overlap of the gate electrode structure 204 with the region 205A may be defined by the lateral extension of the implantation mask 265A, which may be formed on the basis of superior surface conditions of the device 200, thereby enhancing the overall process uniformity.

Thereafter the further processing may be continued, as previously explained with reference to FIGS. 2a-2f.

FIG. 2l schematically illustrates the semiconductor device 250 according to illustrative embodiments in which a plurality of floating body storage transistors 200 may be provided in an SOI configuration, i.e., the buried insulating layer 202 is provided between the substrate 201 and the respective well or semiconductor regions 203 of the individual transistors 200. The transistors 200 thus represent respective memory cells of a memory area of the device 250, wherein the laterally asymmetric configuration of the basic well doping may provide the possibility of reducing the overall dimensions of each individual memory cell and also reducing the voltages required for programming/reading the respective memory cells, as previously explained. That is, at least at a specific depth in the individual semiconductor regions 203, the well dopant concentration of the floating body region is higher at the drain side compared to the source side, thereby providing a locally increased impact ionization probability, while, in the remaining portion of the floating body region having the reduced well dopant concentration, a reduced charge-carrier recombination rate may be achieved. Thus, the gate length and thus the overall lateral transistor dimension of the device 200 may be reduced, thereby increasing the information storage density in the device 250, while also reducing operating voltages, which may allow a corresponding reduction of peripheral components required for operating the memory cells including the transistors 200.

FIG. 2m schematically illustrates a top view of the semiconductor device 250 according to illustrative embodiments, in which the plurality of transistors 200, for instance, in the form of N-channel transistors or in the form of P-channel transistors, may be combined to form an array 210 of memory cells including the transistors 200 having the laterally asymmetric configuration of the halo regions or well dopant concentration, as previously explained. The array 210 may further comprise respective metal lines 211, 212, acting as bit line and select line, which may typically be formed in a metallization layer of the device 250. Furthermore, respective contacts 211C, 212C may provide electrical connection between the drain regions 205 and source regions 215 with the lines 212, 211, respectively. Furthermore, as illustrated, respective word lines WL may be represented by the gate electrode structures 204. It should be appreciated that the array 210 as illustrated in FIG. 2m may represent a “one-dimensional” array, for convenience, wherein typically a plurality of transistor elements may be provided along a transistor width direction, which represents the vertical direction in FIG. 2m, so as to define a two-dimensional memory array. Moreover, in one illustrative embodiment, the transistors 200 may be oriented in a parallel manner with respect to the transistor width direction such that the laterally asymmetric configuration of the halo region 205H may be accomplished on the basis of an additional non-masked tilted implantation process, as previously explained with reference to FIG. 2c. In other illustrative embodiments, the transistors may be oriented according to other criteria, wherein the asymmetric patterning of the basic well dopant concentration may be accomplished by a masked well doping implantation process, as previously explained.

FIG. 2n schematically illustrates the semiconductor device 250 according to further illustrative embodiments in which an asymmetric floating body RAM area, for instance in the form of the array 210, may be provided in an appropriate circuit portion of the device 250, or the device 250 may represent a memory device usable as storage device for other components external to the device 250. For this purpose, the device 250 may further comprise a voltage step-up converter 230, which may be configured to boost the supply voltage of the device 250 to an appropriate high value required for operating the array 210, as previously explained with reference to FIG. 1b. Furthermore, a memory controller 220 may be provided to control read and write operations in the array 210 by appropriately applying voltage signals to the respective lines, such as the word line and the bit line and select line 211, 212, as previously explained. Additionally, in one illustrative embodiment, the device 250 may further comprise an input/output circuitry 240 to allow access to the asymmetric RAM memory 210 by external devices.

During operation of the device 250, appropriate high voltages may be supplied during reading and writing to individual cells of the memory array 210, wherein, due to the increased performance of the parasitic transistor achieved by the asymmetric configuration of the well doping, i.e., the halo region 205H, a reduced operating voltage may be used between the drain and source regions 205, 215 compared to conventional symmetric designs. Thus, a reduced amount of leakage currents may be generated during the operation of the device 250, while additionally the chip area consumed by the up-converter 230 may also be reduced, thereby providing increased information storage density of the device 250, since, for a given number of memory cells of the array 210, the size of the auxiliary circuit, i.e., step-up converter 230, may be reduced.

FIG. 2o schematically illustrates the semiconductor device 250 according to a further illustrative embodiment. As shown, the device 250 may represent an advanced integrated circuit including a central processing unit (CPU) 270, which may be operatively connected to a static RAM area, which may, for instance, comprise memory cells having low access time, for instance, based on conventional registers. For example, the static RAM area 280 may represent a cache memory for the CPU 270, for example, including a level 1 cache memory and a level 2 cache memory. Moreover, the device 250 may comprise the asymmetric RAM array 210, for instance in the form of an array as previously described, which may comprise respective transistors having increased dopant concentration at the drain side, as previously explained with reference to the transistors 200. Moreover, a peripheral circuitry 220 may be provided that may control the memories 210, 280, for instance by providing appropriate control signals and supply voltages as required for the operation of the memories 280, 210. In one illustrative embodiment, the memory array 210 having the asymmetrical dopant concentration may represent a level 3 cache memory for the CPU 270. In this case, enhanced storage density may be achieved, since the memory array 210 may have a significantly increased storage density compared to static RAM arrays, as previously explained, and may also provide significantly increased storage density compared to dynamic RAM devices, since no storage capacitor is required. Due to the enhanced reliability and increased retention time, enhanced overall performance of the device 250 may be accomplished compared to conventional devices including highly complex CPUs, since increased storage capacity may be provided or additional functionality may be incorporated into the device 250 due to the scalability of the RAM array 210, as previously explained.

As a result, the present disclosure provides semiconductor devices and manufacturing techniques for obtaining an asymmetric configuration of the well dopant concentration in floating body storage transistors, thereby enabling operation of the transistors on the basis of reduced voltages during read and programming operations. That is, due to the local increase of the basic well doping at the drain side, an abrupt PN junction may be established, while also the probability of impact ionization at the drain side may be increased, while the moderately low well doping concentration at the source side may provide the high emitter efficiency of the parasitic bipolar transistor. Furthermore, a moderately low basic well doping in the remaining portion of the floating body region may reduce the recombination rate therein, which may contribute to an increased retention time and also a reduced operational voltage for switching on the parasitic bipolar transistor. Furthermore, due to the possibility of locally increasing the well dopant concentration at the drain side, a reduction of the punch-through effect may be achieved, thereby imparting increased punch-through immunity to the transistor, which may allow the usage of reduced gate length for given operating voltages, thereby enhancing the scalability of respective floating body memory cells.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A floating body storage transistor, comprising:
a gate electrode formed above a semiconductor region and separated therefrom by a gate insulation layer;
a drain region and a source region formed in said semiconductor region, said drain region and source region defined by a dopant species of a first conductivity type; and
a floating body region located in said semiconductor region adjacent to and in contact with said drain region and said source region so as to form a first PN junction with said drain region and a second PN junction with said source region, said floating body region being defined by a dopant species of a second conductivity type that is opposite to said first conductivity type, a concentration of said dopant species of the second conductivity type being higher at said first PN junction as compared to said second PN junction.

2. The floating body storage transistor of claim 1, wherein a dopant gradient of said first PN junction is steeper compared to a dopant gradient of said second PN junction.

3. The floating body storage transistor of claim 1, wherein a degree of counter-doping caused by said dopant species of said first conductivity type in said source region at a specified depth increases from said gate electrode towards an interface formed by an isolation structure and said source region.

4. The floating body storage transistor of claim 1, wherein a degree of counter-doping caused by said dopant species of said first conductivity type in said source region at a specified depth is substantially constant along a direction from said gate electrode towards an interface formed by an isolation structure and said source region.

5. The floating body storage transistor of claim 1, further comprising a buried insulating layer formed below and in contact with said semiconductor region.

6. The floating body storage transistor of claim 1, further comprising an isolated well region embedded in said semiconductor region, wherein said isolated well region is defined by a dopant species of said second conductivity type.

7. The floating body storage transistor of claim 1, wherein said first conductivity type is an N-type conductivity.

8. The floating body storage transistor of claim 1, wherein said first conductivity type is a P-type conductivity.

9. A semiconductor device, comprising:
a plurality of floating body storage transistors configured to store information on the basis of charge storage in a floating body region, each of said plurality of floating body storage transistors having a well region with an increased well dopant concentration at a PN junction at a drain side compared to a PN junction at a source side.

10. The semiconductor device of claim 9, wherein each of said plurality of floating body storage transistors is a part of a respective one of a memory cell of a memory area of said semiconductor device.

11. The semiconductor device of claim 10, further comprising a CPU core operatively connected to said memory area.

12. The semiconductor device of claim 11, further comprising a static RAM area operatively connected to said CPU core and said memory area.

13. The semiconductor device of claim 9, further comprising a buried insulating layer formed below and in contact with each of said well regions to define an SOI configuration.

14. The semiconductor device of claim 9, wherein each of said well regions is provided as an isolated well region embedded in a semiconductor material.

15. A method of forming a storage transistor, the method comprising:
defining a well region in a semiconductor region in a laterally asymmetric manner with respect to a drain region and a source region to be formed in said well region; and
forming said drain region and said source region by introducing a dopant species of a first conductivity type to define a first PN junction connecting to said drain region and a second PN junction connecting to said source region.

16. The method of claim 15, wherein defining said well region comprises laterally asymmetrically introducing a dopant species of a second conductivity type opposite to said first conductivity type into a semiconductor region to obtain a higher concentration at said first PN junction relative to said second PN junction.

17. The method of claim 16, wherein laterally asymmetrically introducing the dopant species of said second conductivity type comprises forming a gate electrode structure above said semiconductor region and performing at least one implantation process with a tilt angle and using said gate electrode as an implantation mask.

18. The method of claim 16, wherein laterally asymmetrically introducing the dopant species of said second conductivity type comprises masking said source region and performing an implantation process to introduce the dopant species of said second conductivity type.

19. The method of claim 18, further comprising forming a gate electrode structure above said semiconductor region prior to performing said implantation process.

20. The method of claim 18, further comprising forming a gate electrode structure above said semiconductor region after performing said implantation process.

21. The method of claim 15, wherein forming said drain region and said source region comprises introducing a first concentration of a dopant species of said first conductivity type, forming a spacer element on sidewalls of a gate electrode structure and introducing a second concentration of a dopant species of said first conductivity type, wherein said second concentration is higher than said first concentration.

22. The method of claim 15, wherein forming said drain region and said source region comprises forming a spacer element on sidewalls of a gate electrode structure for defining a final offset of said drain region and source region with respect to said gate electrode prior to introducing a dopant species of said first conductivity type.

23. The method of claim 17, further comprising implanting a dopant species of said second conductivity type into said semiconductor region prior to forming said gate electrode structure and laterally asymmetrically increasing a concentration of the species of said second conductivity type during said tilted implantation process to form laterally asymmetrically positioned halo regions.

24. The method of claim 23, wherein forming said drain and source regions comprises positioning a first halo region to form a PN junction with said drain region and positioning a second halo region to be embedded in said source region.
